(19) United States
(12) Patent Application Publication
(10) Pub. No.: US 2008/0225598 A1
(43) Pub. Date: Sep. 18, 2008

(54) Flash memory and method for checking status register by block unit

(75) Inventors: Jin-Sung Jung, Chungcheongnam-do (KR); Jong-Kook Kim, Chungcheongnam-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/075,398

(22) Filed: Mar. 11, 2008

(30) Foreign Application Priority Data
Mar. 16, 2007 (KR) 10-2007-0026121

(51) Int. Cl. G11C 16/34; G11C 29/44

(52) U.S. Cl. 365/185.22; 365/201

(57) ABSTRACT

Provided is a test method of a NAND flash memory. The method includes programming a page of a selected memory block in the flash memory; accumulating a program result of the page; and repeating the programming of other pages and the accumulating of the program result of the other pages until all pages in the selected memory block are programmed.

### CROSS-REFERENCE TO RELATED APPLICATIONS

This U.S. non-provisional patent application claims priority under 35 U.S.C. §119 to Korean Patent Application No. 10-2007-0026121, filed on Mar. 16, 2007, the entire contents of which are hereby incorporated by reference.

### FIELD OF THE INVENTION

The present invention disclosed herein relates to a NAND flash memory and more particularly, to a method of testing a NAND flash memory.

### BACKGROUND OF THE INVENTION

In general, a flash memory is a kind of a non-volatile memory device, and thus is capable of electrically erasing memory contents stored in a flash memory cell. The flash memory with the above characteristic is typically used as a substitute or supplement for a portable computer's hard disk in order to repeatedly perform a write or read operation.

FIG. 1 is a flowchart illustrating a page program of a typical NAND flash memory. FIG. 2 is a timing diagram illustrating a page program of the typical NAND flash memory of FIG. 1.

Referring to FIGS. 1 and 2, a command 80h is inputted through an I/Ox pin to prepare a page program operation of the NAND flash memory in operation 101. In operation 102, an address is inputted to the NAND flash memory through the I/Ox pin. In operation 103, data is inputted to the NAND flash memory through the I/Ox pin. In operation 104, a command 10h is inputted through the I/Ox pin in order to perform the page program operation of the NAND flash memory. The NAND flash memory performs the page program operation during a page program time tPROG.

In operation 105, a value of a status register is read to verify the page program operation of the NAND flash memory. That is, a command 70h is inputted through the I/Ox pin to verify the page program operation of the NAND flash memory.

The NAND flash memory determines whether an I/O 6 pin is 1 or not and an R/Bb pin is 1 or not as illustrated in Table 1. If the I/O 6 pin is 1 or the R/Bb pin is 1 in the NAND flash memory, it performs operation 107, and if not, it performs operation 106. That is, it maintains operation 106 until the I/O 6 pin is 0 and the R/Bb pin is 0 in the NAND flash memory.

As illustrated in Table 1, the NAND flash memory determines whether an I/O 0 pin is 0 or not. If the I/O 0 pin of the NAND flash memory is 0, it is confirmed that the page program operation of the NAND flash memory is normally performed. If not, it is confirmed that the page program operation of the NAND flash memory is abnormally performed and thus causes an error in operation 107.

Table 1 defines read status registers of the NAND flash memory.

TABLE 1

| I/O No. | Page Program | Block Erase | Read | Definition |
|---|---|---|---|---|
| I//O 0 | Pass/Fail | Pass/Fail | Not use | Pass: “0” |
| | | | | Fail: “1” |
| I//O 1 | Not use | Not use | Not use | Don't-care |
| I//O 2 | Not use | Not use | Not use | Don't-care |
| I//O 3 | Not use | Not use | Not use | Don't-care |
| I//O 4 | Not use | Not use | Not use | Don't-care |
| I//O 5 | Not use | Not use | Not use | Don't-care |
| I//O 6 | Ready/Busy | Ready/Busy | Ready/Busy | Ready: “0” |
| | | | | Busy: “1” |
| I//O 7 | Write Protect | Write Protect | Write Protect | Protected: “0” |
| | | | | Not |
| | | | | Protected: “1” |

A monitoring burn-in tester (MBT) is a tester for determining whether an operation of a device under test (DUT) is normally performed or not in a high temperature. A burn-in board (BIB) is mounted to the MBT to perform a test on a plurality of DUTs in a high temperature. The DUT is a NAND flash memory.

FIG. 3 is a block diagram of a BIB of a typical MBT. Referring to FIG. 3, a first BIB BIB1 includes 320 NAND flash memories, and one MBT includes 48 BIBs BIB1 to BIB48.

All the NAND flash memories in the first BIB BIB1 simultaneously perform write operations and read operations by a scan unit. That is, once read operations of 8 NAND flash memories are completed during a first scan scan1, read operations of 8 NAND flash memories are performed during a second scan scan2.

Since the MBT can test a large number of NAND flash memories compared to general test equipment, it is usually used in a burn-in test and for general tests.

FIG. 4a is a flowchart illustrating a program operation of a typical NAND flash memory. Operations 401 through 407 are the same as the page program operations of the NAND flash memory of FIG. 1. Accordingly, overlapping description will be omitted for conciseness.

Referring to FIGS. 3 and 4A, the program operation initializes a block and a page of the NAND flash memory, and initializes a scan of the BIB in operation 400. That is, a first block, a first page, and a first scan scan1 of a first BIB BIB1 are selected.

In operations 401 through 404, write operations of 320 NAND flash memories in first to fortieth scans scan1 to scan 40 are performed. In operation 405, a status register is read to determine whether or not first page program operations of 8 NAND flash memories in the first scan scan1 were normally performed. In operation 406, this operation repeats until the I/O 6 pin is 0 and the R/Bb pin is 0 in the NAND flash memory.

The NAND flash memory determines whether the I/O 0 pin is 0 or not. In operation 407, if the I/O 0 pin of the NAND flash memory is 0, it is confirmed that a page program operation of the NAND flash memory was normally performed, and if not, it is confirmed that a page program operation of the NAND flash memory caused an error. That is, it is confirmed whether or not the first page program operations of the 8 NAND flash memories in the first scan scan1 were normally performed.

In operations 408 and 409, if there was no error detected in the status register read from the operation 407, the status register of the second scan scan2 is read. In operations 409 and 410, when a fortieth scan scan40 is completed in a first page of the NAND flash memory during operation 408, a second page program operation of the NAND flash memory will be performed. In operations 411 and 412, when a fortieth scan scan40 is completed in a 128^{th} page of the NAND flash memory during operation 409, a first page program operation of a second block will be performed.

The NAND flash memory reads a status register each time a page program operation for one page is performed, as illustrated in FIG. 4B. If the status register is read each time the NAND flash memory performs one page program operation in mass production, a test time of the NAND flash memory increases.

### SUMMARY OF THE INVENTION

In accordance with the present invention, provided are a NAND flash memory having reduced test time and a test method thereof.

According to one aspect of the present invention, provided is a method for testing a flash memory, the method including: programming a page of a selected memory block in the flash memory; accumulating a program result of the page; and programming a next page and the accumulating of the program result of the next page, until all pages in the selected memory block are programmed.

The method can further include reading the program result after accumulating the program result for each programmed page, until all pages in the selected memory block are programmed.

Programming the page through the reading of the program result can be repeatedly performed until all memory blocks of the flash memory are programmed.

The flash memory can include one of a NAND flash memory, a NOR flash memory, a phase-change memory, and a ferroelectric random access memory.

In accordance with another aspect of the present invention, provided is a method for testing a flash memory, which includes: performing a sequential page program operation to sequentially program a plurality of pages of a selected memory block in the flash memory, wherein the sequential page program operation includes a program interval and a program verify interval, including accumulating a program result of a corresponding page in a register during the program verify interval; and reading the program result of the corresponding page, stored in the register, after the sequential page program operation is completed.

The performing of the sequential page program operation and the reading of the program result can be repeatedly performed until all memory blocks of the flash memory are programmed.

The flash memory can include one of a NAND flash memory, a NOR flash memory, a phase-change memory, and a ferroelectric random access memory.

In accordance with still another aspect of the present invention, provided is a flash memory including a plurality of memory blocks, each memory block with a plurality of pages, the flash memory including: a status register configured to store a program verify result while a program operation is performed to program a selected page; and a status register accumulator configured to accumulate a program result about each page of a selected memory block while a sequential program operation is performed-to sequentially program pages in the selected memory block of the flash memory, wherein the sequential page program operation includes a program interval and a program verify interval, and a program result of a corresponding page is accumulated in a register during the program verify interval.

The flash memory can further include: a write/read circuit configured to control a write operation and a read operation of the flash memory; and a control circuit configured to output a result of the read operation of the flash memory.

In accordance with even another aspect of the present invention, provided is a test system that includes: a flash memory; and a tester testing the flash memory. The flash memory includes a plurality of memory blocks, each memory block with a plurality of pages, the flash memory further including: a status register configured to store a program verify result while a program operation is performed to program a selected page; and a status register accumulator configured to accumulate a program result for each page of a selected memory block while a sequential program operation is performed to sequentially program pages in the selected memory block of the flash memory, wherein the sequential page program operation includes a program interval and a program verify interval, and a program result of a corresponding page is accumulated in a register during the program verify interval.

The tester can be configured to output a status read command to the flash memory after all pages of a selected memory block in the flash memory are programmed.

### BRIEF DESCRIPTION OF THE FIGURES

The accompanying figures are included to provide a further understanding of the present invention, and are incorporated in and constitute a part of this specification. The drawings illustrate exemplary embodiments in accordance with the present invention and, together with the description, serve to explain principles of the present invention. In the figures:

FIG. 1 is a flowchart illustrating prior art page program of a typical NAND flash memory;

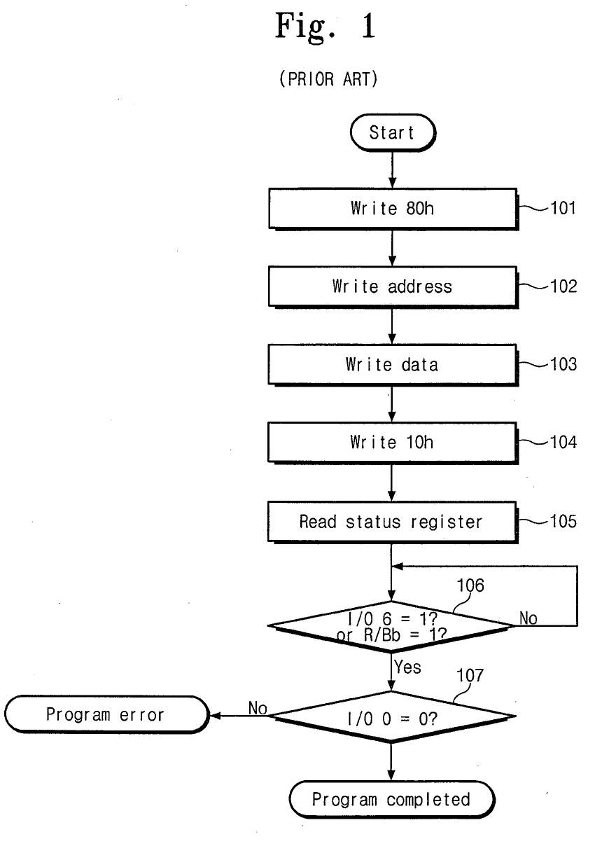

FIG. 2 is a timing diagram illustrating prior art page program of the typical NAND flash memory of FIG. 1;

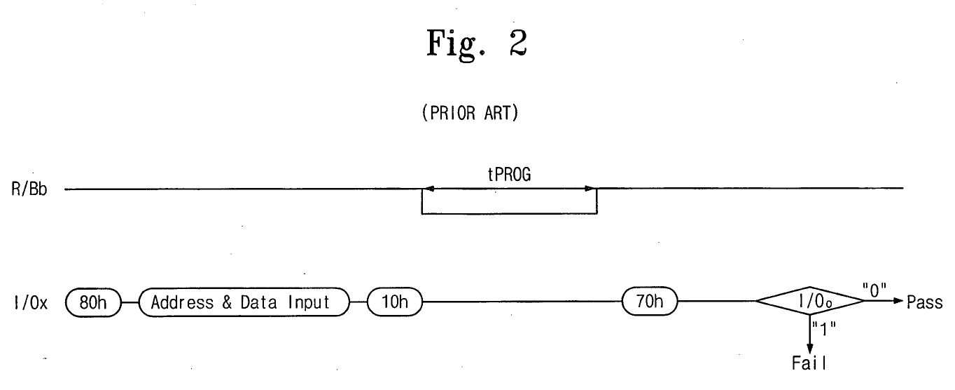

FIG. 3 is a block diagram of a prior art BIB of a typical MBT;

FIG. 4A is a flowchart illustrating a prior art program operation of a typical NAND flash memory;

FIG. 4B is a block diagram of a prior art test method of a typical NAND flash memory;

FIG. 5 is a flowchart representing an embodiment of a method of programming a NAND flash memory according to an aspect of the present invention;

FIG. 6 is a block diagram of an embodiment of a NAND flash memory according to another aspect of the present invention; and

FIG. 7 is a flowchart illustrating an embodiment of a test method of a NAND flash memory of FIG. 6.

### DETAILED DESCRIPTION OF PREFERRED EMBODIMENTS

Preferred embodiments in accordance with aspects of the present invention will be described below in more detail with reference to the accompanying drawings. The present invention may, however, be embodied in different forms and should not be construed as limited to the embodiments set forth herein.

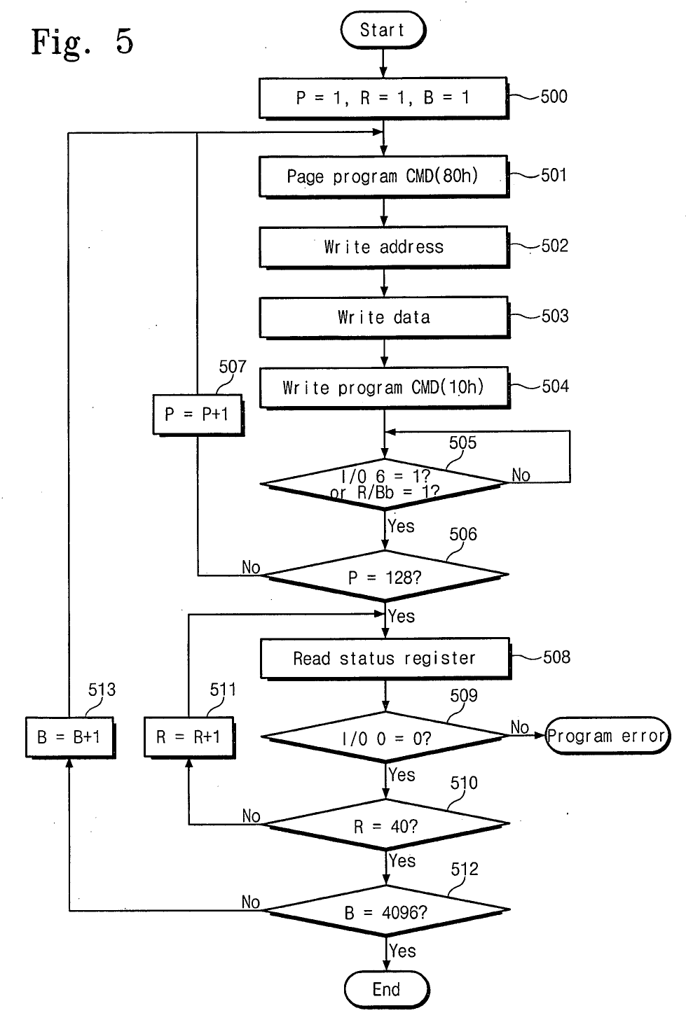

FIG. 5 is a flowchart representing a method of programming a NAND flash memory according to an aspect of the present invention.

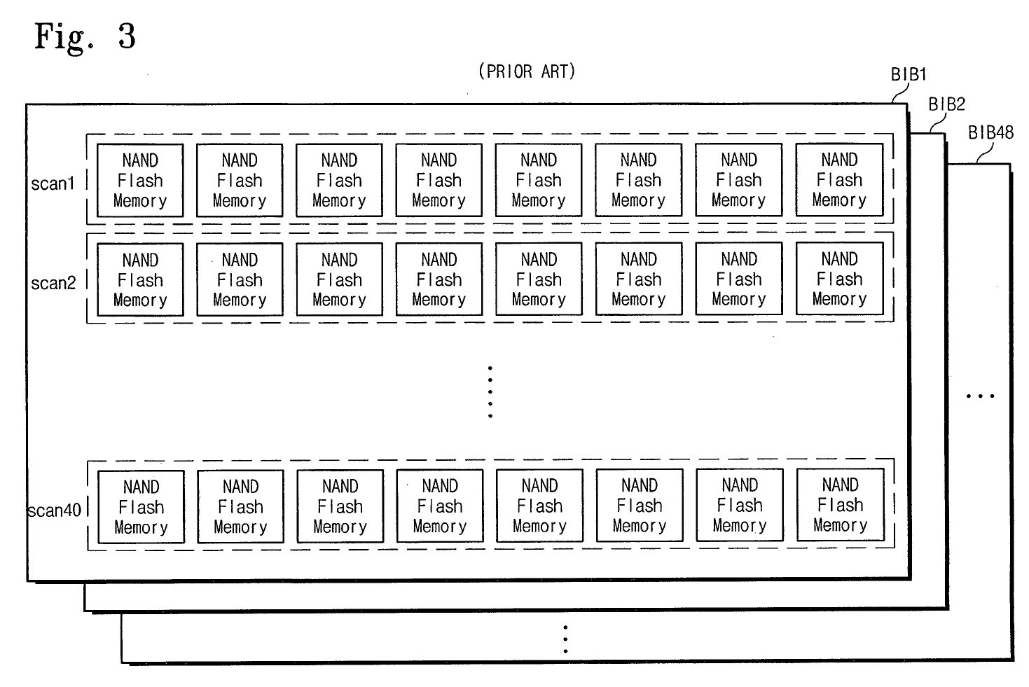

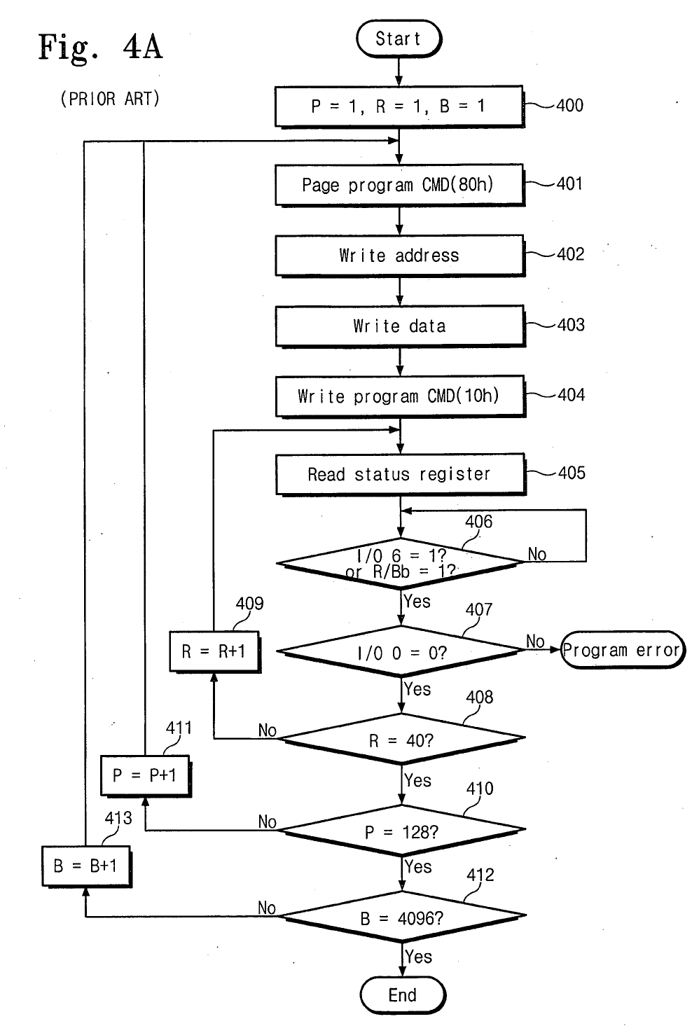

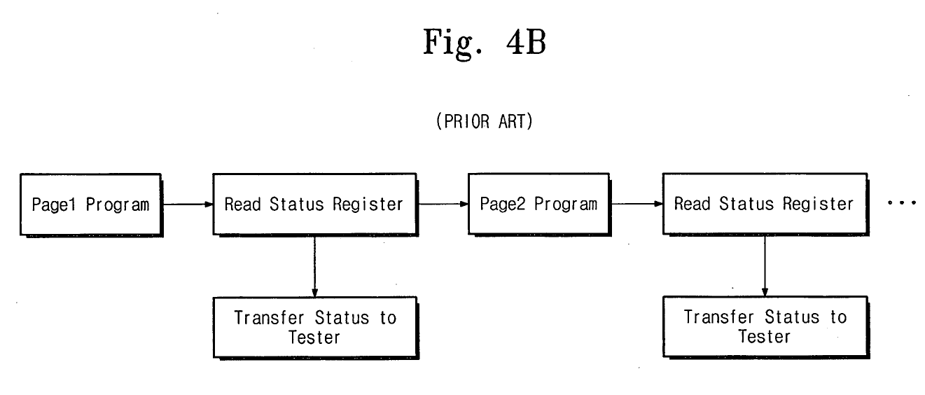

Referring to device of FIG. 3 and the method of FIG. 5, a block and a page of the NAND flash memory are initialized and a scan of a burn-in board (BIB) is initialized in operation 500. That is, a first block and a first page of the NAND flash memory and a first scan scan1 of a first BIB BIB1 are selected. In operations 501 to 504, write operations of 320 NAND flash memories in first to fortieth scans scan1 to scan40 are performed. The operations 500 and 504 are the same as the page program operation of the NAND flash memory of FIG. 4A.

Referring to FIGS. 3 and 5, the NAND flash memory maintains operation 505 until the I/O 6 pin is 0 and the R/Bb pin is 0 in the NAND flash memory. In operations 506 and 507, when a fortieth scan scan40 is completed in a first page of the NAND flash memory during operation 505, a second page program operation of the NAND flash memory will be performed. In operation 508, a status register is read to determine whether or not first page program operations of 8 NAND flash memories in the first scan scan1 are normally performed. The NAND flash memory determines whether or not the I/O 0 pin is 0. In operation 509, if the I/O 0 pin of the NAND flash memory is 0, it is confirmed that a page program operation of the NAND flash memory is normally performed, and if not, it is confirmed that a page program operation of the NAND flash memory causes an error. That is, it is confirmed whether or not the first page program operations of the 8 NAND flash memories in the first scan scan1 are normally performed. In operations 510 and 511, if there is no error detected in the status register read from the operation 508, the status register of the second scan scan2 is read. In operations 512 and 513, when a fortieth scan scan40 is completed in a 128^{th} page of the NAND flash memory during operation 510, a second page program operation of the NAND flash memory will be performed.

A typical test method of a NAND flash memory reads a status register after performing a test by a page unit. But the test method in accordance with the present invention reads a status register after performing a test by a block unit.

Accordingly, the test method of the present invention reduces a test time when compared to the typical test method.

TABLE 2

| | | The number |
|---|---|---|
| | 8G MLC NAND flash | of reading |
| | memory | status registers |
| Typical method | 128 page * 40 scan * 4098 | 20, 981, 760 |
| | Block | |
| Method in accordance | 40 scan * 4098 Block | 163, 840 |
| with the present invention | | |

On the assumption that a read time of a single status register is about 20 μs, the read time of the status registers is about 419.6 sec according to the typical read method, and the read time of the status registers is about 3.3 sec in the method of the present embodiment, as follows:

Typical method: 20,981,760*20 μs=419, 638,200 μs,

Present Embodiment: 163,920*20 μs=3,278,400 μs

That is, referring to Table 2, the test method of the present embodiment has a test time of the read status registers, which is 128 times faster than that of the typical method.

Substantially, in a case of a test time of an 8 G MLC NAND flash memory (MLC), the test time of typical read method is about 6,961 sec and the test time of the read method according to the present embodiment is about 880 sec.

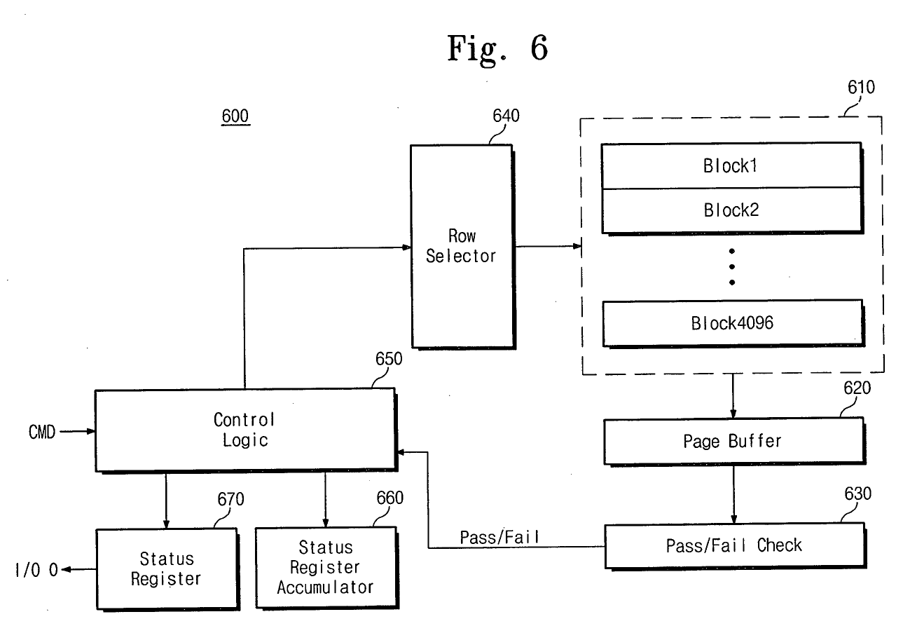

FIG. 6 is a block diagram of an embodiment of a NAND flash memory according to another aspect of the present invention.

Referring to FIG. 6, a NAND flash memory 600 includes a memory cell array 610, a page buffer 620, a pass/fail check circuit 630, a row selector 640, a control logic 650, a status register accumulator 660, and a status register 670.

The NAND flash memory 600 includes the memory cell array 610, and the memory cell array 610 includes at least one memory block. The number of memory blocks Block1 to Block4O96 of FIG. 6 is 4096.

The row selector 640 and the page buffer circuit 620 include a write/read circuit controlling a write operation and a read operation of the NAND flash memory 600. The row selector 640 selects one of the word lines in the memory cell array 610. During a program operation, the row selector 640 supplies a program voltage to the selected word line and supplies a pass voltage to the unselected word line. The page buffer circuit 620 detects data stored in memory cells of word lines selected during a read operation or a read verify operation. During a read operation, the data detected by the page buffer circuit 620 determines whether or not data values delivered through the row selector 640 are pass data values.

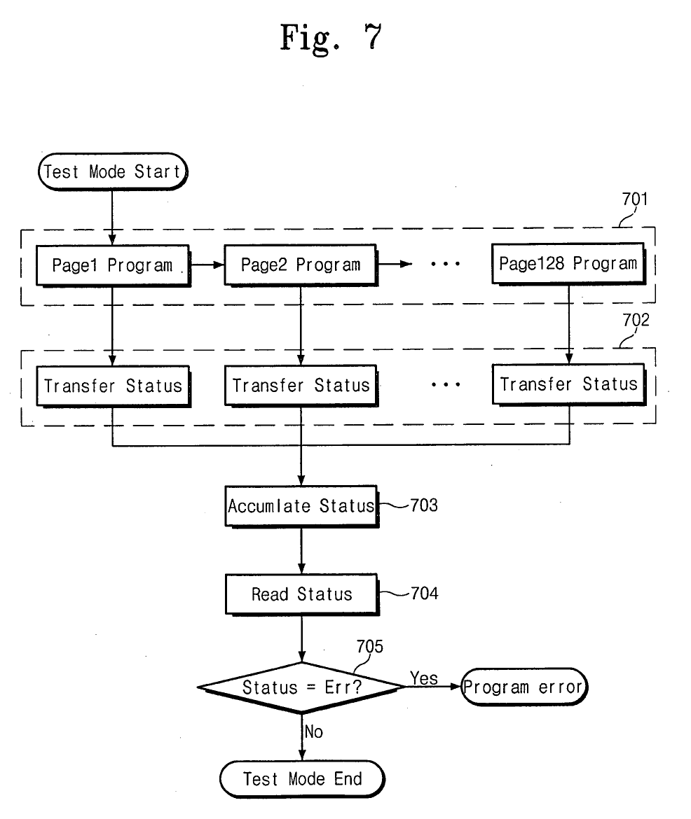

The control logic 650 and the pass/fail check circuit 630 constitute a control circuit configured to output the result of the read operation of the flash memory. The control logic 650 controls general operations of the NAND flash memory 600. The status register accumulator 660 receives pass/fail information, inputted from the pass/fail check circuit 630, from the control circuit 650 and stores them. That is, if it is passed, a pass status is stored, and if it is failed, a fail status is stored. While storing a fail status, a fail status is stored even when a pass status is inputted. The status register 670 outputs the data of the status register stored in the status register accumulator 660 through an I/O 0 pin. Detailed operations of status register accumulator 660 and the status register 670 are described with reference to FIG. 7.

FIG. 7 is a flowchart illustrating an embodiment of a test method of a NAND flash memory of FIG. 6. FIG. 7 illustrates a test method of one block in the NAND flash memory 600.

Referring to FIGS. 6 and 7, the NAND flash memory 600 performs a program operation on a first page in a first block Block1. Additionally, the NAND flash memory 600 performs a program operation on a second page through a 128^{th} page in the first block Block1 in operation 701. Once the first page program operation is completed, the pass/fail check circuit 630 delivers a pass/fail signal Pass/Fail to the control circuit 650. Additionally, second through 128^{th} page program operations are completed, the pass/fail check circuit 630 delivers a pass/fail signal Pass/Fail to the control circuit 650 in operation 702. The status register accumulator 660 receives the pass/fail signal Pass/Fail from the control circuit 650, and stores them in operation 703. For example, if it is passed, a pass status is stored, and if it is failed, a fail status is stored. While storing a fail status, a fail status is stored even when a pass status is inputted. The status register 670 outputs the data of the status register in the status register accumulator 660 through an I/O 0 pin in operation 704. If the I/O 0 pin of the NAND flash memory 600 is 0, it is confirmed that the page program operation is normally performed. If not, the page program operation causes an error in operation 705.

Accordingly, in accordance with the present invention, the number of reading status registers is reduced, such that a test time of the NAND flash memory can be decreased.

Additionally, the present invention can be applied to a NAND flash memory, a NOR flash memory, a phase-change memory, and a ferroelectric random access memory, as examples.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for testing a flash memory, comprising:
programming a page of a selected memory block in the flash memory;
accumulating a program result of the page; and
programming a next page of the selected memory block and accumulating of the program result of the next page, until all pages in the selected memory block are programmed.

2. The method of claim 1, further comprising reading the program result after accumulating the program result for each programmed page until all pages in the selected memory block are programmed.

3. The method of claim 2, wherein the programming of the page through the reading of the program result is repeatedly performed until all memory blocks of the flash memory are programmed.

4. The method of claim 1, wherein the flash memory comprises one of a NAND flash memory, a NOR flash memory, a phase-change memory, and a ferroelectric random access memory.

5. A method for testing a flash memory, comprising:
performing a sequential page program operation to sequentially program a plurality of pages of a selected memory block in the flash memory,
wherein the sequential page program operation includes a program interval and a program verify interval, including accumulating a program result of a corresponding page in a register during the program verify interval; and
reading the program result of the corresponding page, stored in the register, after the sequential page program operation is completed.

6. The method of claim 5, wherein the performing of the sequential page program operation and the reading of the program result are repeatedly performed until all memory blocks of the flash memory are programmed.

7. The method of claim 6, wherein the flash memory comprises one of a NAND flash memory, a NOR flash memory, a phase-change memory, and a ferroelectric random access memory.

8. A flash memory including a plurality of memory blocks, each memory block with a plurality of pages, the flash memory comprising:
a status register configured to store a program verify result while a program operation is performed to program a selected page; and
a status register accumulator configured to accumulate a program result for each page of a selected memory block while a sequential program operation is performed to sequentially program pages in the selected memory block of the flash memory,
wherein the sequential page program operation includes a program interval and a program verify interval, and a program result of a corresponding page is accumulated in a register during the program verify interval.

9. The flash memory of claim 8, further comprising:
a write/read circuit configured to control a write operation and a read operation of the flash memory; and
a control circuit configured to output a result of the read operation of the flash memory.

10. A test system comprising:
the flash memory including a plurality of memory blocks, each memory block with a plurality of pages, the flash memory comprising:
a status register configured to store a program verify result while a program operation is performed to program a selected page; and
a status register accumulator configured to accumulate a program result for each page of a selected memory block while a sequential program operation is performed to sequentially program pages in the selected memory block of the flash memory,
wherein the sequential page program operation includes a program interval and a program verify interval, and a program result of a corresponding page is accumulated in a register during the program verify interval; and
a tester configured to test the flash memory.

11. The test system of claim 10, wherein the tester is configured to output a status read command to the flash memory after all pages of a selected memory block in the flash memory are programmed.
